(19) United States
(12) Patent Application Publication
(10) Pub. No.: US 2012/0153983 A1
(43) Pub. Date: Jun. 21, 2012

(54) PROBE FIXING DEVICE

(75) Inventors: KANG WU, Shenzhen City (CN); BO TIAN, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 12/979,343

(22) Filed: Dec. 28, 2010

(30) Foreign Application Priority Data
Dec. 21, 2010 (CN) 201010598594.2

(51) Int. Cl. G01R 31/00

(52) U.S. Cl. 324/756.04

(57) ABSTRACT

A fixing device for fixing probes of an oscillograph. The fixing device includes a base, a holding member for holding the probe, and an arm connected between the base and the holding member. The arm is made of pliable metal material. Therefore, the arm may be bent and deformed easily.

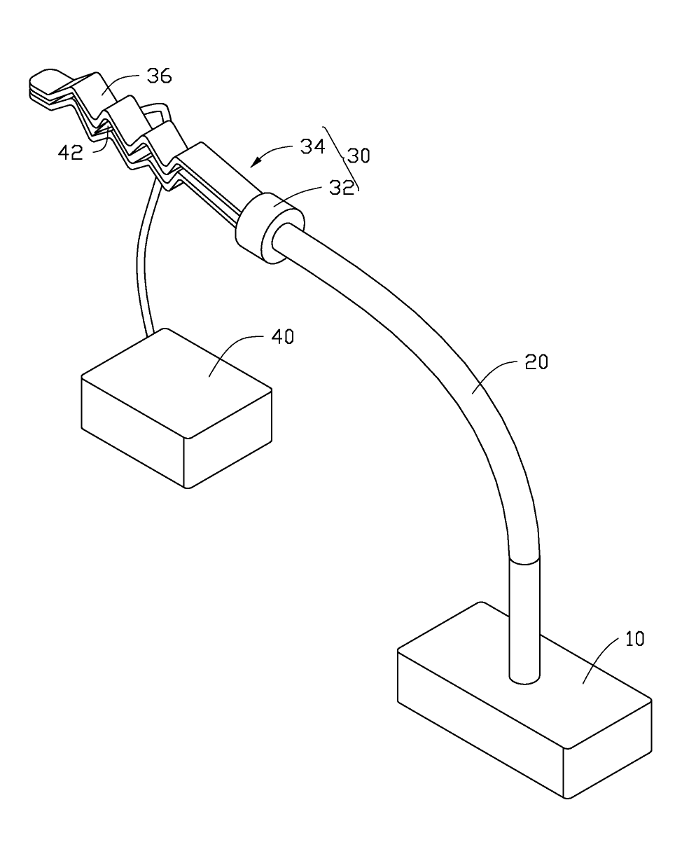

### CROSS-REFERENCE OF RELATED APPLICATION

Relevant subject matter is disclosed in a pending U.S. patent application, titled “PROBE ASSEMBLY”, with the application Ser. No. 12/978,532, which is assigned to the same assignee as this patent application.

### BACKGROUND

1. Technical Field

The present disclosure relates to a fixing device for fixing a probe of an oscillograph.

2. Description of Related Art

Oscillographs are often used for testing circuit boards of electronic devices. However, probes of an oscillograph are generally connected to the oscillograph by cables that are too flexible to assist with holding the probes in place when contacted to part of the circuit board. As a result, in use, people or a fixing member needs to hold the probes. Furthermore, in use, the fixing members must be arranged at a side of a portion of a circuit board needing to be tested, which is inconvenient, and occupies a large area on the circuit board.

### BRIEF DESCRIPTION OF THE DRAWING

Many aspects of the present embodiments can be better understood with reference to the following drawing. The components in the drawing are not necessarily drawn to scale, the emphasis instead being placed upon clearly illustrating the principles of the present embodiments. Moreover, in the drawing, the view is schematic.

The figure is an isometric view of an exemplary embodiment of a fixing device for fixing a probe of an oscillograph.

### DETAILED DESCRIPTION

The disclosure, including the accompanying drawing, is illustrated by way of example and not by way of limitation. It should be noted that references to “an” or “one” embodiment in this disclosure are not necessarily to the same embodiment, and such references mean at least one.

Referring to the figure, an exemplary embodiment of a fixing device is used for fixing a probe 42 of an oscillograph 40. The fixing device includes a base 10, an arm 20, and a holding member 30.

The base 10 is substantially rectangular, and is made of heavy material.

The arm 20 is made of pliable metal material, but still stiff enough that it can maintain a shape once bent to that shape until acted on by a force greater than the stiffness, such as what an operator could easily apply with their hands when positioning the arm 20.

The holding portion 30 includes a connection portion 32 and a clamping portion 34 extending from a first side of the connection portion 32. The clamping portion 34 includes two spaced wave-shaped holding pieces 36.

Opposite ends of the arm 20 are respectively connected to a top of the base 10 and a second side of the connection portion 32 opposite to the clamping portion 34.

In use, the fixing member is placed at a side of a circuit board (not shown) needing to be tested. The probe 42 is clamped by the clamping portion 34 between the holding pieces 36. The arm 20 can be bent to a desired shape to help maintain the holding member 30. Thereby, the probe is fixed to test a portion on a circuit board. As the base 10 is made of heavy material, the base 10 may not move while the arm 20 is operated.

As the holding pieces 36 are wave-shaped, the probe 42 may be fixed between the holding pieces 36 tightly. Furthermore, the holding pieces 36 may clamp many probes 42.

It is believed that the present embodiments and their advantages will be understood from the foregoing description, and they will be apparent that various changes may be made thereto without departing from the spirit and scope of the description or sacrificing all of their material advantages, the examples hereinbefore described merely being exemplary embodiment.

What is claimed is:

1. A fixing device for a probe, the fixing device comprising:
a base;
a holding member for holding the probe; and
an arm connected between the base and the holding member, wherein the arm is made of pliable metal material that can be shaped into a desired form and maintain that form until acted on to reshape the form.

2. The fixing device of claim 1, wherein the base is made of heavy material.

3. The fixing device of claim 2, wherein the holding member comprises a connection portion connected to the arm opposite to the base, and a clamping portion extending from the connection portion, to clamp the probe.

4. The fixing device of claim 3, wherein the clamping portion comprises two spaced wave-shaped holding pieces to sandwich the probe between the holding pieces.
